(19) United States
(12) Patent Application Publication
(10) Pub. No.: US 2025/0015763 A1
(43) Pub. Date: Jan. 9, 2025

(54) DOHERTY AMPLIFIER

(71) Applicant: Mitsubishi Electric Corporation, Tokyo (JP)

(72) Inventor: Katsuya KATO, Tokyo (JP)

(73) Assignee: Mitsubishi Electric Corporation, Tokyo (JP)

(21) Appl. No.: 18/711,099

(22) PCT Filed: Mar. 28, 2022
(86) PCT No.: PCT/JP2022/015098

§ 371 Date: May 16, 2024

(51) Int. Cl. H03F 1/02; H03F 1/56; H03F 3/21

(52) U.S. Cl. CPC H03F 1/0288; H03F 1/565; H03F 3/21; H03F 2200/222; H03F 2200/387

(57) ABSTRACT

A Doherty amplifier according to the first disclosure includes an input terminal; an output terminal; a first main transistor provided in a first signal path connecting the input terminal and the output terminal; a second main transistor provided on the output terminal side of the first main transistor in the first signal path; a first peak transistor provided in a second signal path connecting the input terminal and the output terminal; and a second peak transistor provided on the output terminal side of the first peak transistor in the second signal path, wherein one of the first peak transistor and the second peak transistor, and the first main transistor are provided on a first semiconductor chip, and another of the first peak transistor and the second peak transistor, and the second main transistor are provided on a second semiconductor chip.

### FIELD

The present disclosure relates to a Doherty amplifier.

### BACKGROUND

PTL 1 discloses a Doherty amplifier in which main transistors of two stages are integrated on one semiconductor chip, peak transistors of two stages are integrated on one semiconductor chip, and these semiconductor chips are mounted on a resin substrate.

### CITATION LIST

### Patent Literature

[PTL 1] U.S. Pat. No. 10,381,984 B

### SUMMARY

### Technical Problem

Sufficient reduction of characteristic fluctuation caused by manufacturing variation is important for the amplifier in order to improve yield. The manufacturing variation generally occurs in each lot, each wafer, or each semiconductor chip. In a transistor, the manufacturing variation is caused by, for example, a parasitic capacitance Cds between a source and a drain. In a matching circuit, the manufacturing variation is caused by, for example, a MIM (Metal-Insulator-Metal) capacitance.

In the Doherty amplifier, a signal amplified by a main transistor path and a signal amplified by a peak transistor path are preferably power-combined without loss. In other words, in a case where a passing phase of the entire main transistor path is denoted by θmain, and a passing phase of the entire peak transistor path is denoted by θpeak, the passing phase θmain and the passing phase θpeak are desirably equal to each other. If a phase difference occurs between the passing phase θmain and the passing phase θpeak, combination loss occurs, and saturation output power of the Doherty amplifier is reduced. Therefore, the Doherty amplifier is generally designed such that the difference between the passing phase θmain and the passing phase Øpeak becomes zero.

In PTL 1, for example, a case where the parasitic capacitance Cds and the MIM capacitance are varied to be increased in the main transistor path, and the parasitic capacitance Cds and the MIM capacitance are varied to be reduced in the peak transistor path may occur due to semiconductor manufacturing variation. When the capacitances are increased, the passing phase is delayed, whereas when the capacitances are reduced, the passing phase is advanced. As a result, in the above-described case, the difference between the passing phase θmain and the passing phase θpeak may be excessively increased, and the saturation output power may be reduced.

An object of the present disclosure is to provide a Doherty amplifier that can suppress reduction in saturation output power caused by manufacturing variation.

### Solution to Problem

A Doherty amplifier according to the first disclosure includes an input terminal; an output terminal; a first main transistor provided in a first signal path connecting the input terminal and the output terminal; a second main transistor provided on the output terminal side of the first main transistor in the first signal path; a first peak transistor provided in a second signal path connecting the input terminal and the output terminal; and a second peak transistor provided on the output terminal side of the first peak transistor in the second signal path, wherein one of the first peak transistor and the second peak transistor, and the first main transistor are provided on a first semiconductor chip, and another of the first peak transistor and the second peak transistor, and the second main transistor are provided on a second semiconductor chip.

A Doherty amplifier according to the second disclosure includes an input terminal; an output terminal; a first main transistor provided in a first signal path connecting the input terminal and the output terminal; a first peak transistor provided in a second signal path connecting the input terminal and the output terminal; a first matching circuit provided in the first signal path; and a second matching circuit provided in the second signal path, wherein the first main transistor and the first peak transistor are provided on a first semiconductor chip, and the first matching circuit and the second matching circuit are provided on a second semiconductor chip.

### Advantageous Effects of Invention

The Doherty amplifier according to the first disclosure, one of the first peak transistor and the second peak transistor, and the first main transistor are provided on the first semiconductor chip. The other of the first peak transistor and the second peak transistor, and the second main transistor are provided on the second semiconductor chip. As a result, the one of the first peak transistor and the second peak transistor, and the first main transistor can be caused to have similar variation. Further, the other of the first peak transistor and the second peak transistor, and the second main transistor can be caused to have similar variation. This makes it possible to suppress a phase difference between the first signal path and the second signal path.

In the Doherty amplifier according to the second disclosure, the first main transistor and the first peak transistor are provided on the first semiconductor chip, and the first matching circuit and the second matching circuit are provided on the second semiconductor chip. As a result, the first main transistor and the first peak transistor can be caused to have similar variation. In addition, the first matching circuit and the second matching circuit can be caused to have similar variation. This makes it possible to suppress a phase difference between the first signal path and the second signal path.

### BRIEF DESCRIPTION OF DRAWINGS

FIG. 1 is a plan view of a Doherty amplifier according to Embodiment 1.

FIG. 2 is a circuit diagram of the Doherty amplifier according to Embodiment 1.

FIG. 3 is a diagram to explain passing phases of the Doherty amplifier.

FIG. 4 is a plan view of a Doherty amplifier according to a first comparative example.

FIG. 5 is a plan view of a Doherty amplifier according to a second comparative example.

FIG. 6 is a circuit diagram of the Doherty amplifier according to the second comparative example.

FIG. 7 is a diagram illustrating calculation results of the saturation output power of the Doherty amplifier according to the comparative example.

FIG. 8 is a diagram illustrating calculation results of the saturation output power of the Doherty amplifier according to Embodiment 1.

FIG. 9 is a diagram illustrating an interstage matching circuit according to a first modification of Embodiment 1.

FIG. 10 is a diagram illustrating an interstage matching circuit according to a second modification of Embodiment 1.

FIG. 11 is a diagram illustrating an interstage matching circuit according to a third modification of Embodiment 1.

FIG. 12 is a diagram illustrating an interstage matching circuit according to a fourth modification of Embodiment 1.

FIG. 13 is a plan view of a Doherty amplifier according to Embodiment 2.

FIG. 14 is a plan view of a Doherty amplifier according to a modification of Embodiment 2.

FIG. 15 is a plan view of a Doherty amplifier according to Embodiment 3.

FIG. 16 is a plan view of a Doherty amplifier according to Embodiment 4.

FIG. 17 is a plan view of a Doherty amplifier according to a modification of Embodiment 4.

FIG. 18 is a plan view of a Doherty amplifier according to Embodiment 5.

FIG. 19 is a diagram illustrating a structure of a transistor.

### DESCRIPTION OF EMBODIMENTS

A Doherty amplifier according to each embodiment will be described with reference to the drawings. Identical or corresponding constitutional elements are given the same reference numerals, and the repeated description of such constitutional elements may be omitted.

### Embodiment 1

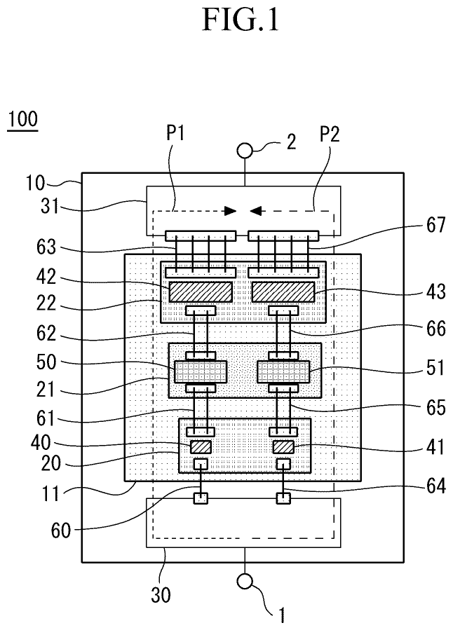

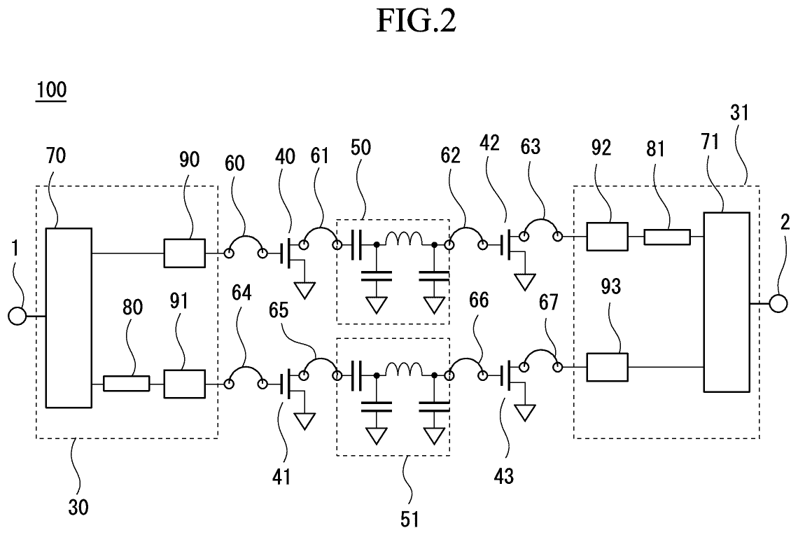

FIG. 1 is a plan view of a Doherty amplifier 100 according to Embodiment 1. FIG. 2 is a circuit diagram of the Doherty amplifier 100 according to Embodiment 1. The Doherty amplifier 100 is used for, for example, wireless communication. The Doherty amplifier 100 includes an input terminal 1 and an output terminal 2. A first main transistor 40 is provided in a first signal path P1 connecting the input terminal 1 and the output terminal 2. In the first signal path P1, a second main transistor 42 is provided on the output terminal 2 side of the first main transistor 40. A first peak transistor 41 is provided in a second signal path P2 connecting the input terminal 1 and the output terminal 2. In the second signal path P2, a second peak transistor 43 is provided on the output terminal 2 side of the first peak transistor 41.

The first peak transistor 41 and the first main transistor 40 are provided on a semiconductor chip 20. The second peak transistor 43 and the second main transistor 42 are provided on a semiconductor chip 22. In other words, the first peak transistor 41 and the first main transistor 40 are provided on the same semiconductor substrate. Further, the second peak transistor 43 and the second main transistor 42 are provided on the same semiconductor substrate.

In the first signal path P1, a first interstage matching circuit 50 is provided between the first main transistor 40 and the second main transistor 42. In the second signal path P2, a second interstage matching circuit 51 is provided between the first peak transistor 41 and the second peak transistor 43. The first interstage matching circuit 50 and the second interstage matching circuit 51 are provided on a semiconductor chip 21. In other words, the first interstage matching circuit 50 and the second interstage matching circuit 51 are provided on the same semiconductor substrate.

The Doherty amplifier 100 is integrated on a resin substrate 10. The input terminal 1 is connected to a circuit 30 provided on the resin substrate 10. The circuit 30 includes a divider circuit 70, an input delay line 80, an input matching circuit 90 of the main transistor, and an input matching circuit 91 of the peak transistor. The circuit 30 is connected to a gate terminal of the first main transistor 40 and a gate terminal of the first peak transistor 41 through bonding wires 60 and 64, respectively.

The semiconductor chip 20, the semiconductor chip 21, and the semiconductor chip 22 are die-bonded to a die pad 11. The semiconductor chip 20 and the semiconductor chip 21 are connected by bonding wires 61 and 65. The semiconductor chip 21 and the semiconductor chip 22 are connected by bonding wires 62 and 66. A drain terminal of the second main transistor 42 and a drain terminal of the second peak transistor 43 are connected to a circuit 31 provided on the resin substrate 10 by bonding wires 63 and 67, respectively. The circuit 31 includes a combiner circuit 71, an output delay line 81, an output matching circuit 92 of the main transistor, and an output matching circuit 93 of the peak transistor. The circuit 31 is connected to the output terminal 2.

Each of the semiconductor chips 20 and 22 is formed of, for example, a SiC substrate. Each of the first main transistor 40, the first peak transistor 41, the second main transistor 42, and the second peak transistor 43 is, for example, a GaN-HEMT (High Electron Mobility Transistor). Each of the first main transistor 40, the first peak transistor 41, the second main transistor 42, and the second peak transistor 43 includes a parasitic capacitance Cds between a source and a drain.

The semiconductor chip 21 is formed of an inexpensive substrate made of, for example, GaAs or Si. For example, an MIM capacitor is integrated on the semiconductor chip 21. Each of the first interstage matching circuit 50 and the second interstage matching circuit 51 includes, for example, two parallel capacitances, one series capacitance, and one series inductor. The first interstage matching circuit 50 and the second interstage matching circuit 51 may be designed in consideration of parasitic inductances of the bonding wires 61, 62, 65, and 66.

The resin substrate 10 is made of a material, for example, FR4. A thickness of the resin substrate 10 is 200 μm to 500 μm. Reduction in thickness of the resin substrate 10 enables reduction in thermal resistances of the transistors. In contrast, increase in thickness of the resin substrate 10 enables multilayer wiring. As a result, an integration degree of the circuit can be enhanced to achieve downsizing and cost reduction. Note that, in FIGS. 1 and 2, illustration of a drain bias circuit and a gate bias circuit is omitted.

The Doherty amplifier that has high efficiency and low distortion is used as, for example, a transmission power amplifier of a communication base station. In the Doherty amplifier 100, a main transistor biased in class AB or B and a peak transistor biased in class C are combined in parallel by using 24 lines. The λ/4 lines are arranged at an output of one of amplifiers and at an input of the other of the amplifiers. The λ/4 lines correspond to the input delay line 80 and the output delay line 81.

When a large signal is input, the main transistor and the peak transistor operate in a similar manner, and are combined in phase. Therefore, characteristics similar to characteristics of a 2-combined amplifier are obtained, and large saturation output power can be achieved. In contrast, when a small signal is input, only the main transistor operates, and the 24 line connected to the output side of the main transistor functions as an impedance inverter. Therefore, high efficiency caused by high load impedance can be achieved. Accordingly, the Doherty amplifier 100 can achieve high efficiency within a wide output power range.

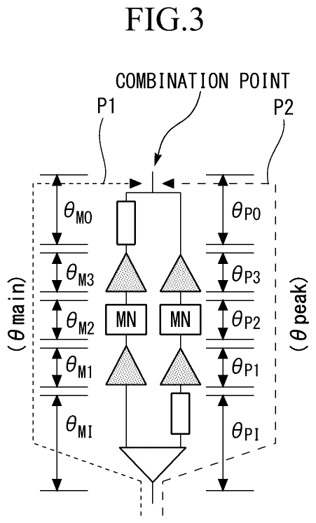

FIG. 3 is a diagram to explain passing phases of the Doherty amplifier. FIG. 3 illustrates the passing phases on respective circuit end surfaces of a two-stage Doherty circuit. A passing phase of the entire first signal path P1 on the main transistor side is denoted by θmain. A passing phase from an input signal terminal to an input end of a first-stage transistor chip is denoted by θMI. A passing phase of the first-stage transistor chip is denoted by θM1. A passing phase of an interstage matching circuit is denoted by θM2. A passing phase of a final-stage transistor chip is denoted by θM3. A passing phase from an output end of the final-stage transistor to a combination point is denoted by θMO. The passing phase θmain is a sum of the passing phases θMI, θM1, θM2, θM3, and θMO.

Likewise, a passing phase of the entire second signal path P2 on the peak transistor side is denoted by θpeak. A passing phase from the input signal terminal to an input end of a first-stage transistor chip is denoted by θPI. A passing phase of the first-stage transistor chip is denoted by θP1. A passing phase of an interstage matching circuit is denoted by θP2. A passing phase of a final-stage transistor chip is denoted by θP3. A passing phase from an output end of the final-stage transistor to the combination point is denoted by θPO. The passing phase θmain is a sum of the passing phases θPI, θP1, θP2, θP3, and θPO.

In the Doherty amplifier, to power-combine the signal amplified by the first signal path P1 and the signal amplified by the second signal path P2 without loss, the passing phase θmain and the passing phase θpeak are required to be equal to each other. If a phase difference occurs therebetween, combination loss occurs, and the saturation output power of the Doherty amplifier is reduced.

Next, a comparative example of the present embodiment is described. As the Doherty amplifier, for example, there is an MMIC (Monolithic Microwave Integrated Circuit) in which most part of the two-stage Doherty amplifier circuit is integrated on one semiconductor chip. In a millimeter waveband, a circuit size is not generally ignorable as compared with a wavelength. Therefore, it is necessary to configure the Doherty amplifier by a distributed constant circuit. The MMIC can be manufactured with precise dimensions. Further, the Doherty amplifier can be downsized. On the other hand, in a case where a high-performance semiconductor substrate such as a GaN on SiC is used, a manufacturing cost may be increased because a chip area is large in the MMIC.

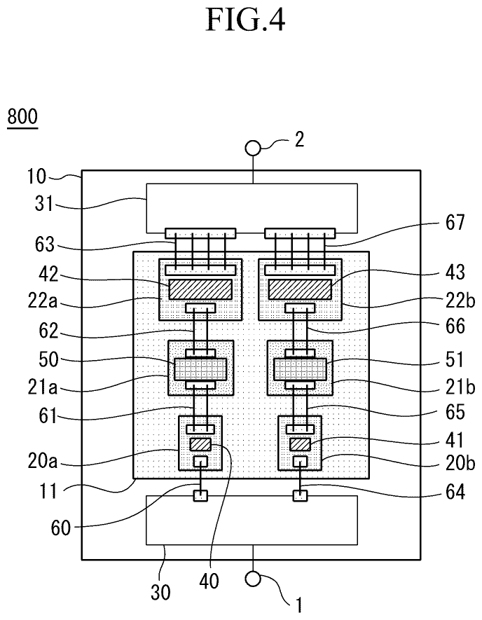

FIG. 4 is a plan view of a Doherty amplifier 800 according to a first comparative example. In the Doherty amplifier 800, the first main transistor 40, the first interstage matching circuit 50, and the second main transistor 42 are integrated on different semiconductor chips 20a to 22a. Further, the first peak transistor 41, the second interstage matching circuit 51, and the second peak transistor 43 are integrated on different semiconductor chips 20b to 22b. In this case, the matching circuits can be integrated on inexpensive GaAs or Si substrates, and only the transistors can be integrated on high-performance semiconductor substrates. As a result, in an L-band, an S-band, and the like with low frequency, cost reduction can be achieved while maintaining the performance.

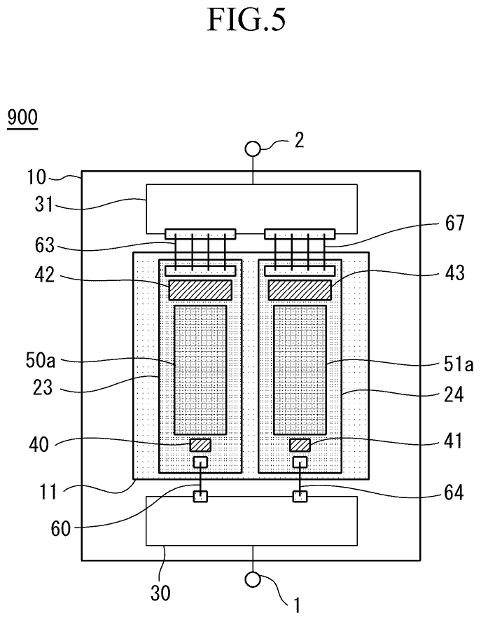

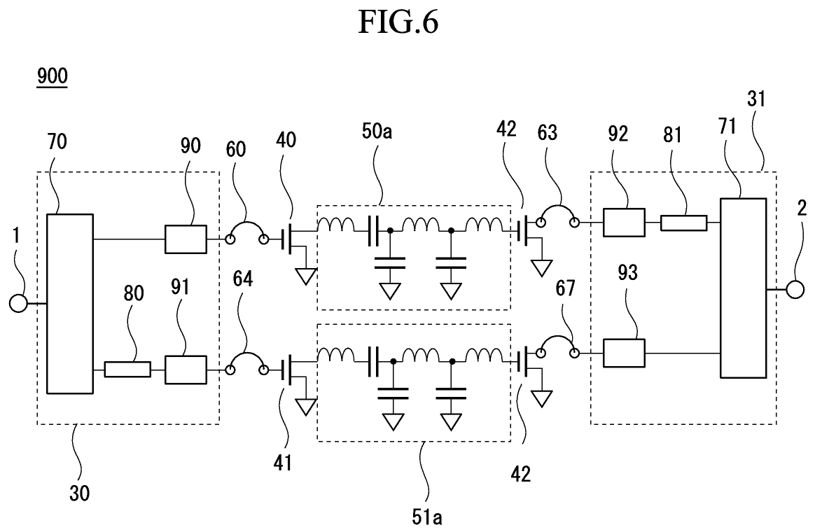

FIG. 5 is a plan view of a Doherty amplifier 900 according to a second comparative example. FIG. 6 is a circuit diagram of the Doherty amplifier 900 according to the second comparative example. In the Doherty amplifier 900, the first main transistor 40, an interstage matching circuit 50a, and the second main transistor 42 are integrated on one semiconductor chip 23. Further, the first peak transistor 41, an interstage matching circuit 51a, and the second peak transistor 43 are integrated on one semiconductor chip 24. This configuration also makes it possible to downsize the Doherty amplifier 900.

In the Doherty amplifiers 800 and 900, the parasitic capacitances Cds of the transistors and the MIM capacitance of the matching circuit may be simultaneously increased in the first signal path P1, and the parasitic capacitances Cds of the transistors and the MIM capacitance of the matching circuit may be simultaneously reduced in the second signal path P2, due to semiconductor manufacturing variation. When the capacities are increased, the passing phases are delayed, whereas when the capacities are reduced, the passing phases are advanced. In other words, the passing phases θM1, θM2, and θM3 are increased together, and the passing phases θP1, θP2, and θP3 are reduced together. As a result, a passing phase difference Δ between the passing phase θmain and the passing phase θpeak may be excessively increased. At this time, the saturation output power is reduced.

In contrast, in the present embodiment, the final-stage transistors are integrated on one semiconductor chip, the interstage matching circuits are integrated on one semiconductor chip, and the first-stage transistors are integrated on one semiconductor chip. Variation in the same chip is typically similar. Therefore, even when the parasitic capacitances Cds or the MIM capacitances are varied, each of differences θM1-θP1, θM2-θP2, and θM3-θP3 becomes a value close to zero. Accordingly, the passing phase difference Δ caused by manufacturing variation can be suppressed, and reduction of the saturation output power can be suppressed. Further, in the present embodiment, since the Doherty amplifier 100 includes the plurality of semiconductor chips, the manufacturing cost can be suppressed as compared with the MMIC.

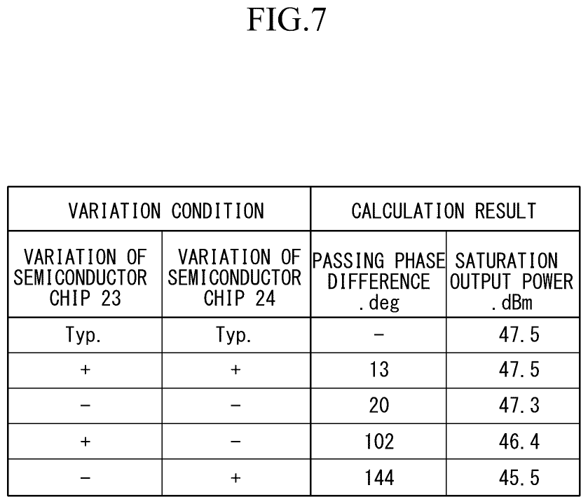

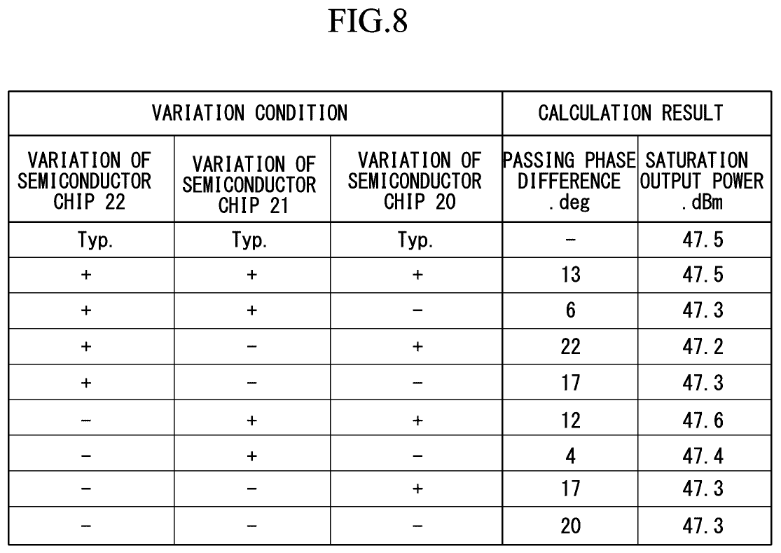

Next, a calculation result of RF characteristic variation of the Doherty amplifier is described. FIG. 7 is a diagram illustrating calculation results of the saturation output power of the Doherty amplifier 900 according to the comparative example. FIG. 8 is a diagram illustrating calculation results of the saturation output power of the Doherty amplifier 100 according to Embodiment 1. In the Doherty amplifier 900 according to the comparative example, it was assumed that inductances of the bonding wires connecting the semiconductor chips are integrated on the semiconductor chips. Variation factors include the parasitic capacitances Cds of the first main transistor 40, the second main transistor 42, the first peak transistor 41, and the second peak transistor 43, and the MIM capacitances of the interstage matching circuits. Calculation was performed in a case where each of the variation factors was varied by +15% from a design center.

In FIGS. 7 and 8, in a case where the parasitic capacitances Cds and the MIM capacitances on the chips are varied to be increased, a plus sign is imparted. In a case where the parasitic capacitances Cds and the MIM capacitances are varied to be reduced, a minus sign is imparted. In a case where the parasitic capacitances Cds and the MIM capacitances have center values, a sign typ is imparted. In the Doherty amplifier 900 according to the comparative example, at the design center, the passing phase difference is zero degrees, and the saturation output power is 47.5 dBm. In a case where the parasitic capacitances Cds and the MIM capacitances of the semiconductor chips 23 and 24 are varied to the plus side or the minus side together, the passing phase difference is 20 degrees, and the saturation output power is reduced by 0.2 dB. However, in a case where the capacitances of the semiconductor chips 23 and 24 are varied in opposite directions, the passing phase difference is 102 degrees or more, and the saturation output power is reduced by 0.9 dB or more.

In contrast, in the Doherty amplifier 100 according to the present embodiment, even in consideration of all of variation combinations, the maximum value of the passing phase difference is 22 degrees, and the saturation output power is reduced by 0.3 dB at the maximum. As described above, in the present embodiment, it is found that variation of the passing phase difference Δ is suppressed, and reduction of the saturation output power is suppressed.

As a modification of the present embodiment, the first interstage matching circuit 50 and the second interstage matching circuit 51 may be provided on different semiconductor chips. Even in this case, variation of the passing phase difference Δ can be suppressed as compared with the Doherty amplifier 900 by integrating the first-stage transistors on one semiconductor chip, and integrating the final-stage transistors on one semiconductor chip.

Further, the second main transistor 42 and the second peak transistor 43 may be provided on different semiconductor chips. Even in this case, variation of the passing phase difference Δ can be suppressed by providing the first main transistor 40 and the first peak transistor 41 on one semiconductor chip 20, and providing the first interstage matching circuit 50 and the second interstage matching circuit 51 on one semiconductor chip 21.

Likewise, the first main transistor 40 and the first peak transistor 41 may be provided on different semiconductor chips. Even in this case, variation of the passing phase difference Δ can be suppressed by providing the second main transistor 42 and the second peak transistor 43 on one semiconductor chip 22, and providing the first interstage matching circuit 50 and the second interstage matching circuit 51 on one semiconductor chip 21. As described above, a part of the circuit in FIG. 1 may be provided on different chips based on an allowable passing phase difference Δ.

In the present embodiment, the first interstage matching circuit 50 and the second interstage matching circuit 51 are provided on one semiconductor chip 21. The configuration is not limited thereto, and input matching circuits of the main transistor and the peak transistor may be provided on one semiconductor chip. In addition, output matching circuits of the main transistor and the peak transistor may be provided on one semiconductor chip.

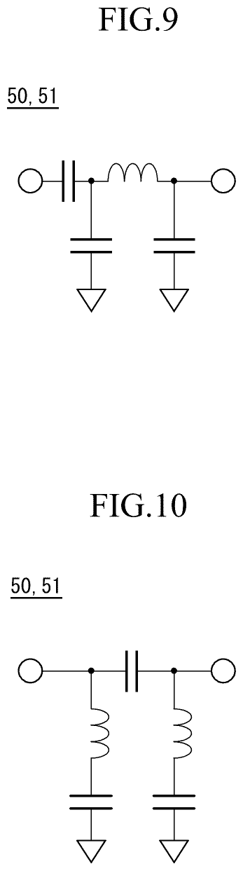

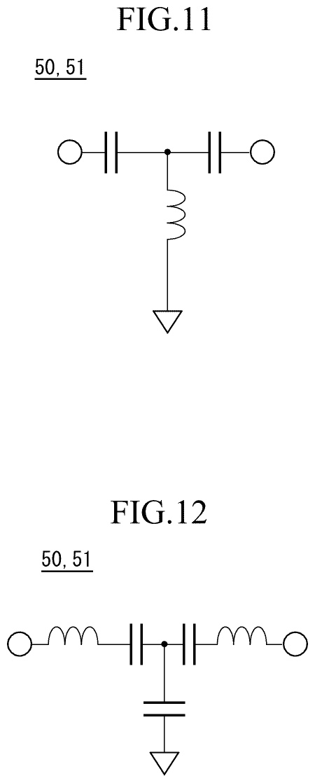

The configurations of the first interstage matching circuit 50 and the second interstage matching circuit 51 are not limited, and the first interstage matching circuit 50 and the second interstage matching circuit 51 may have the other configurations as long as functions similar to the functions of the circuit illustrated in FIG. 2 are realized. FIG. 9 is a diagram illustrating an interstage matching circuit according to a first modification of Embodiment 1. FIG. 10 is a diagram illustrating an interstage matching circuit according to a second modification of Embodiment 1. FIG. 11 is a diagram illustrating an interstage matching circuit according to a third modification of Embodiment 1. FIG. 12 is a diagram illustrating an interstage matching circuit according to a fourth modification of Embodiment 1. As illustrated in FIGS. 9 to 12, each of the first interstage matching circuit 50 and the second interstage matching circuit 51 may be, for example, a π-type circuit, a T-type circuit, or a combination thereof. Further, the first interstage matching circuit 50 and the second interstage matching circuit 51 may be different types of circuits. For example, the first interstage matching circuit 50 may be the circuit illustrated in FIG. 9, and the second interstage matching circuit 51 may be the circuit illustrated in FIG. 10.

The configuration of the circuit 30 is not limited as long as functions similar to the functions of the circuit illustrated in FIG. 2 are realized. This is true of the circuit 31. The Doherty amplifier 100 may be a symmetric Doherty amplifier, or an asymmetric Doherty amplifier in which the main transistor and the peak transistor have different total gate widths. The position of the die pad 11 is not limited to the position on the resin substrate 10, and the die pad 11 may be provided in an opening formed in the resin substrate 10 to expose a heat sink.

These modifications can be applied, as appropriate, to Doherty amplifiers according to the following embodiments. Note that the Doherty amplifiers according to the following embodiments are similar to that of Embodiment 1 in many respects, and thus differences between the Doherty amplifiers according to the following embodiments and those of Embodiment 1 will be mainly described below.

### Embodiment 2

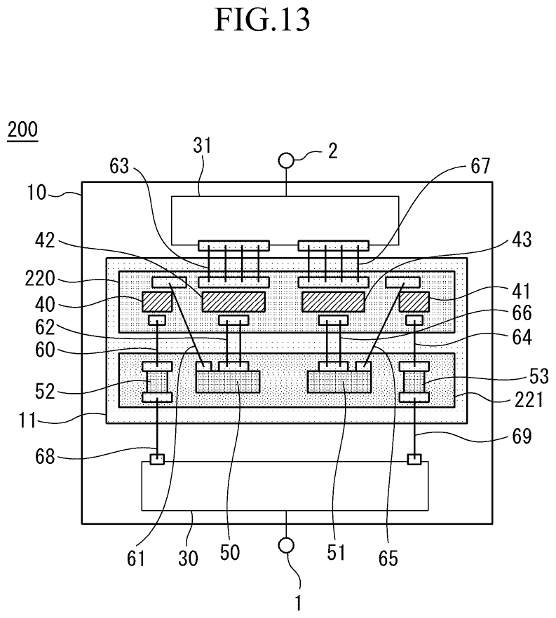

FIG. 13 is a plan view of a Doherty amplifier 200 according to Embodiment 2. In the present embodiment, the first main transistor 40, the first peak transistor 41, the second main transistor 42, and the second peak transistor 43 are provided on a semiconductor chip 220. An input matching circuit 52 of the main transistor and an input matching circuit 53 of the peak transistor are provided on a semiconductor chip 221 provided with the first interstage matching circuit 50 and the second interstage matching circuit 51. The input matching circuits 52 and 53 are parts of input matching circuits 90 and 91, respectively. The input matching circuits 52 and 53 are connected to the circuit 30 through bonding wires 68 and 69, respectively. The other configurations are similar to the configurations in Embodiment 1.

The first main transistor 40 and the first peak transistor 41 at a first stage are arranged outside the second main transistor 42 and the second peak transistor 43 at a final stage. In addition, the input matching circuit 52 and 53 are arranged outside the first interstage matching circuit 50 and the second interstage matching circuit 51.

In the present embodiment, the passing phase difference Δ caused by manufacturing variation can be suppressed, and reduction of the saturation output power can be suppressed. Further, in the present embodiment, the number of chips can be reduced as compared with Embodiment 1. This makes it possible to further downsize the Doherty amplifier 200.

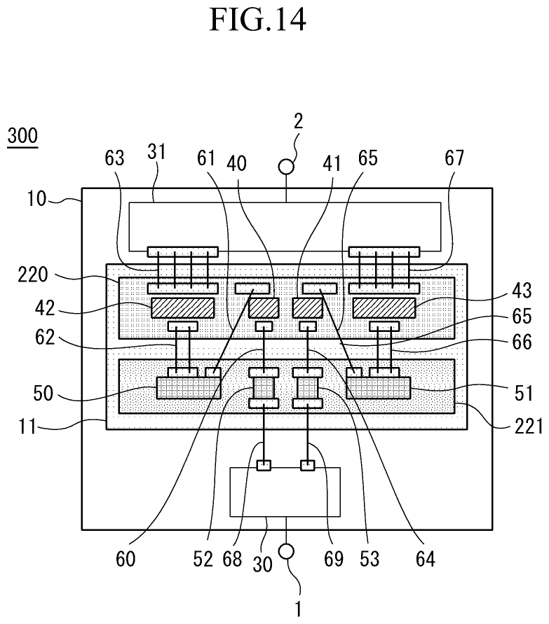

FIG. 14 is a plan view of a Doherty amplifier 300 according to a modification of Embodiment 2. The first main transistor 40 and the first peak transistor 41 at the first stage may be arranged inside the second main transistor 42 and the second peak transistor 43 at the final stage. In this case, the input matching circuit 52 and 53 are arranged inside the first interstage matching circuit 50 and the second interstage matching circuit 51. In the modification, the final-stage transistors liable to be high in temperature during operation can be arranged separately from each other. Therefore, increase in channel temperature of the final-stage transistors can be suppressed, and operation at a high environment temperature is possible.

### Embodiment 3

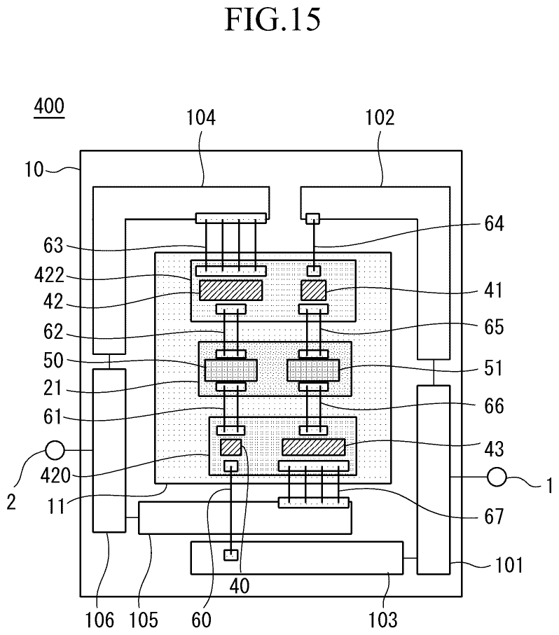

FIG. 15 is a plan view of a Doherty amplifier 400 according to Embodiment 3. In the present embodiment, the second peak transistor 43 and the first main transistor 40 are provided on a semiconductor chip 420, and the first peak transistor 41 and the second main transistor 42 are provided on a semiconductor chip 422. In the present embodiment, the signal path of the main transistors and the signal path of the peak transistors are directed in opposite directions on the semiconductor chips.

The first main transistor 40 and the first peak transistor 41 may have the same gate width, and the second main transistor 42 and the second peak transistor 43 may have the same gate width.

A signal from the input terminal 1 is input to the first peak transistor 41 through a divider circuit 101 and an input matching delay circuit 102. The input matching delay circuit 102 has functions of an input matching circuit and a delay circuit. The signal from the input terminal 1 is also input to the first main transistor 40 through the divider circuit 101 and an input matching circuit 103. The functions of the divider circuit 101, the input matching delay circuit 102, and the input matching circuit 103 are similar to the functions of the circuit 30.

A signal from the second main transistor 42 is output from the output terminal 2 through an output matching delay circuit 104 and a combiner circuit 106. The output matching delay circuit 104 has functions of an output matching circuit and a delay circuit. A signal from the second peak transistor 43 is output from the output terminal 2 through an output matching circuit 105 and the combiner circuit 106. The functions of the output matching delay circuit 104, the output matching circuit 105, and the combiner circuit 106 are similar to the functions of the circuit 31.

In the present embodiment, even when the parasitic capacitances Cds or the MIM capacitances are varied, it is possible to suppress each of differences θM3−θP1, θM2−θP2, and θM1−θP3. Accordingly, the passing phase difference Δ caused by manufacturing variation can be suppressed, and reduction of the saturation output power can be suppressed.

Further, the first main transistor 40 and the first peak transistor 41 have the same transistor size, and the second main transistor 42 and the second peak transistor 43 have the same transistor size. Therefore, as the semiconductor chip 420 and the semiconductor chip 422, the semiconductor chip of the same type or the same specification can be used. In other words, the semiconductor chip 420 and the semiconductor chip 422 can be acquired from the same wafer.

As the semiconductor chip 420 and the semiconductor chip 422, for example, chips adjacent to each other on the wafer are used, which makes it possible to further suppress semiconductor manufacturing variation between the chips. In Embodiment 1, it is necessary to prepare two types of semiconductor chips 20 and 22. In contrast, in the present embodiment, it is sufficient to prepare one type of semiconductor chips 420 and 422. Therefore, this makes it possible to enhance productivity.

As a modification of the present embodiment, the first interstage matching circuit 50 and the second interstage matching circuit 51 may be provided on different semiconductor chips. Even in this case, variation of the passing phase difference Δ can be suppressed as compared with the Doherty amplifier 900 by integrating the first main transistor 40 and the second main transistor 43 on one semiconductor chip, and integrating the second main transistor 42 and the first peak transistor 41 on one semiconductor chip.

Further, the second main transistor 42 and the first peak transistor 41 may be provided on different semiconductor chips. Even in this case, variation of the passing phase difference Δ can be suppressed by providing the first main transistor 40 and the second peak transistor 43 on one semiconductor chip 420, and providing the first interstage matching circuit 50 and the second interstage matching circuit 51 on one semiconductor chip 21.

Likewise, the first main transistor 40 and the second peak transistor 43 may be provided on different semiconductor chips. Even in this case, variation of the passing phase difference Δ can be suppressed by providing the second main transistor 42 and the first peak transistor 41 on one semiconductor chip 422, and providing the first interstage matching circuit 50 and the second interstage matching circuit 51 on one semiconductor chip 21. As described above, a part of the circuit in FIG. 15 may be provided on different chips based on an allowable passing phase difference Δ.

### Embodiment 4

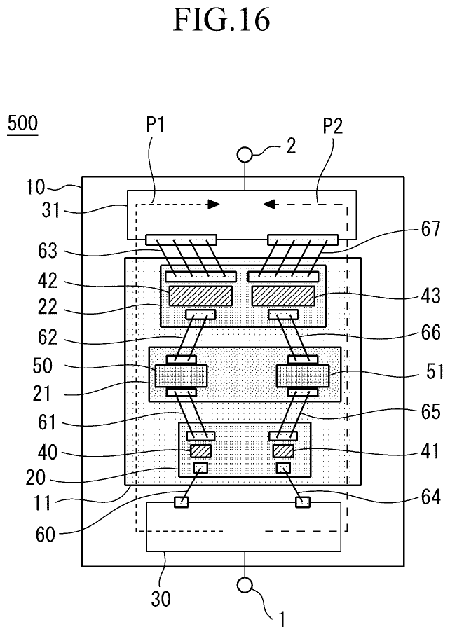

FIG. 16 is a plan view of a Doherty amplifier 500 according to Embodiment 4. The present embodiment is different from Embodiment 1 in that the bonding wires connecting the semiconductor chips in the first signal path P1 and the bonding wires connecting the semiconductor chips in the second signal path P2 are not parallel to each other. The other configurations are similar to the configurations in Embodiment 1. In the present embodiment, the bonding wire 60 and the bonding wire 64 are not parallel to each other, the bonding wire 61 and the bonding wire 65 are not parallel to each other, the bonding wire 62 and the bonding wire 66 are not parallel to each other, and the bonding wire 63 and the bonding wire 67 are not parallel to each other.

An interval between the bonding wires is narrowed on the semiconductor chip 20 side and on the semiconductor chip 22 side on which the transistors are integrated. In other words, an interval between the bonding wires 61 and 65 connecting the semiconductor chip 20 and the semiconductor chip 21 adjacent to the semiconductor chip 20 is widened toward the semiconductor chip 21. Likewise, an interval between the bonding wires 62 and 66 connecting the semiconductor chip 22 and the semiconductor chip 21 adjacent to the semiconductor chip 22 is widened toward the semiconductor chip 21.

In a case where two transistors are integrated on one semiconductor chip, the transistors are adjacent to each other. As a result, the bonding wires connected to the transistors are also adjacent to each other. Electromagnetic fields of the bonding wires adjacent to each other are coupled, which may deteriorate the RF characteristics. In the present embodiment, the bonding wires adjacent to each other are arranged so as not to be parallel to each other, which makes it possible to suppress electromagnetic field coupling between the wires while suppressing the chip sizes.

Further, narrowing the interval between the bonding wires on the semiconductor chip 20 side and on the semiconductor chip 22 side makes it possible to downsize the semiconductor chips 20 and 22. As a result, the Doherty amplifier 500 can be manufactured at low cost.

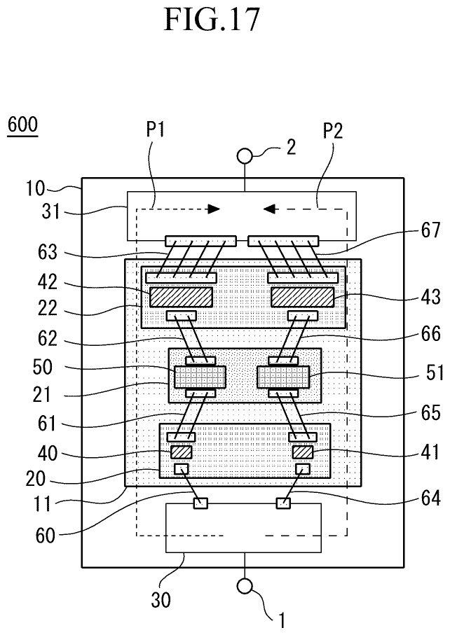

FIG. 17 is a plan view of a Doherty amplifier 600 according to a modification of Embodiment 4. The interval between the bonding wires may be widened on the semiconductor chip 20 side and on the semiconductor chip 22 side on which the transistors are integrated. In addition, the bonding wires not parallel to each other according to the present embodiment may be applied to Embodiments 2 and 3.

### Embodiment 5

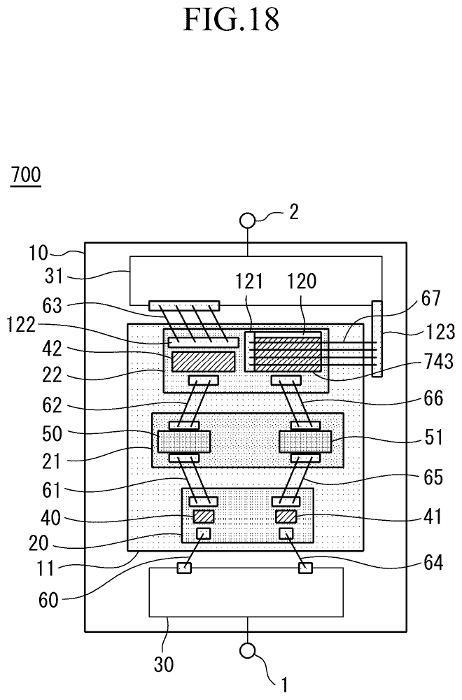

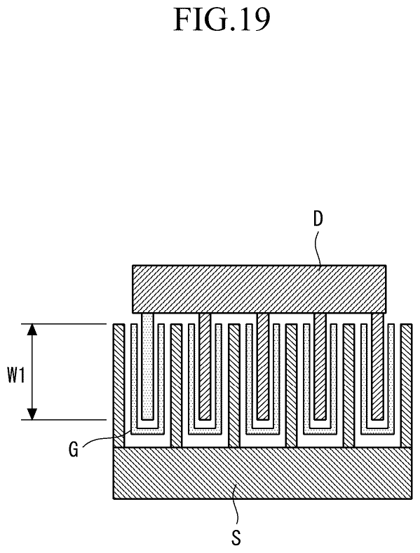

FIG. 18 is a plan view of a Doherty amplifier 700 according to Embodiment 5. In the present embodiment, a second peak transistor 743 is longer than the second main transistor 42 in a signal propagation direction. The signal propagation direction is a direction from the input terminal 1 to the output terminal 2 in FIG. 18. A drain pad 122 of the second main transistor 42 is provided on a side on which the signal is propagated from the second main transistor 42. A drain pad 121 of the second peak transistor 743 is provided adjacent to the second peak transistor 743 in a direction perpendicular to the signal propagation direction.

An output of the second peak transistor 743 is connected to the drain pad 121 arranged perpendicularly to a gate pad through a lead-out line 120. The bonding wire 67 connected to the drain pad 121 is connected to the circuit 31 through a pad 123. The bonding wire 67 connected to the drain pad 121 of the second peak transistor 743 is inclined by 90 degrees or more relative to the bonding wire 63 connected to the drain pad of the second main transistor 42. The other configurations are similar to the configurations in Embodiment 4.

The Doherty amplifier 700 according to the present embodiment is an asymmetric Doherty amplifier in which a total gate width of the second peak transistor 743 is greater than a total gate width of the second main transistor 42. The asymmetric Doherty amplifier can achieve high efficiency at lower output power as compared with a symmetric Doherty amplifier.

FIG. 19 is a diagram illustrating a structure of a transistor. In FIG. 19, D denotes a drain, S denotes a source, G denotes a gate, and W1 denotes a unit gate width. The total gate width is a product of the unit gate width W1 and the number of gates. The transistor becomes long in the signal propagation direction as the unit gate width W1 is longer. When the number of gates is increased, the transistor becomes long in a direction perpendicular to the signal propagation direction. In the present embodiment, the second main transistor 42 and the second peak transistor 743 have the same number of gates, and have different unit gate widths W1.

In a case where the transistors having different unit gate widths W1 are integrated on one semiconductor chip, there is an issue that a blank space is generated by a difference of the unit gate widths W1. In the present embodiment, the thin lead-out line 120 for the output signal of the second peak transistor 743 is laid up to center of the semiconductor chip 22. This makes it possible to provide the drain pad 121 between the second main transistor 42 and the second peak transistor 743. Accordingly, it is possible to prevent the semiconductor chip 22 from becoming long in the signal propagation direction, and to reduce the blank space caused by the difference of the unit gate widths. In addition, the interval between the bonding wires 62 and 66 can be widely secured, and the electromagnetic field coupling can be suppressed. Further, the electromagnetic field coupling between the bonding wires 63 and 68 can also be suppressed. Note that the technical features described in the above embodiments may be combined as appropriate.

### REFERENCE SIGNS LIST

1 input terminal, 2 output terminal, 10 resin substrate, 11 die pad, 20, 20a, 21, 22, 22a, 23, 24 semiconductor chip, 30, 31 circuit, 40 first main transistor, 41 first peak transistor, 42 second main transistor, 43 second peak transistor, 50 first interstage matching circuit, 50a interstage matching circuit, 51 second interstage matching circuit, 51a interstage matching circuit, 52, 53 input matching circuit, 60˜68 bonding wire, 70 divider circuit, 71 combiner circuit, 80 input delay line, 81 output delay line, 90, 91 input matching circuit, 92, 93 output matching circuit, 100 Doherty amplifier, 101 divider circuit, 102 input matching delay circuit, 103 input matching circuit, 104 output matching delay circuit, 105 output matching circuit, 106 combiner circuit, 120 line, 121, 122 drain pad, 123 pad, 200 Doherty amplifier, 220, 221 semiconductor chip, 300, 400 Doherty amplifier, 420, 422 semiconductor chip, 500, 600, 700 Doherty amplifier, 743 second peak transistor, 800, 900 Doherty amplifier, Cds parasitic capacitance, P1 first signal path, P2 second signal path, W1 unit gate width, Δ passing phase difference

1. A Doherty amplifier, comprising:
an input terminal;
an output terminal;
a first main transistor provided in a first signal path connecting the input terminal and the output terminal;
a second main transistor provided on the output terminal side of the first main transistor in the first signal path;
a first peak transistor provided in a second signal path connecting the input terminal and the output terminal; and
a second peak transistor provided on the output terminal side of the first peak transistor in the second signal path, wherein
one of the first peak transistor and the second peak transistor, and the first main transistor are provided on a first semiconductor chip, and
another of the first peak transistor and the second peak transistor, and the second main transistor are provided on a second semiconductor chip.

2. The Doherty amplifier according to claim 1, further comprising:
a first interstage matching circuit provided between the first main transistor and the second main transistor, in the first signal path; and
a second interstage matching circuit provided between the first peak transistor and the second peak transistor, in the second signal path, wherein
the first interstage matching circuit and the second interstage matching circuit are provided on a third semiconductor chip.

3. The Doherty amplifier according to claim 1, wherein
the first peak transistor and the first main transistor are provided on the first semiconductor chip, and
the second peak transistor and the second main transistor are provided on the second semiconductor chip.

4. The Doherty amplifier according to claim 1, wherein
the second peak transistor and the first main transistor are provided on the first semiconductor chip, and
the first peak transistor and the second main transistor are provided on the second semiconductor chip.

5. The Doherty amplifier according to claim 4, wherein
the first main transistor and the first peak transistor have a same gate width, and
the second main transistor and the second peak transistor have a same gate width.

6. The Doherty amplifier according to claim 5, wherein the first semiconductor chip and the second semiconductor chip are semiconductor chips of a same type.

7. The Doherty amplifier according to claim 3, wherein a first bonding wire connecting semiconductor chips in the first signal path and a second bonding wire connecting semiconductor chips in the second signal path are not parallel to each other.

8. The Doherty amplifier according to claim 7, wherein a first bonding wire and a second bonding wire connecting the first semiconductor chip or the second semiconductor chip to an adjacent semiconductor chip are increased in interval therebetween as approaching the adjacent semiconductor chip.

9. The Doherty amplifier according to claim 4, wherein a first bonding wire connecting semiconductor chips in the first signal path and a second bonding wire connecting semiconductor chips in the second signal path are not parallel to each other.

10. The Doherty amplifier according to claim 3, wherein
the second peak transistor is longer than the second main transistor in a signal propagation direction, and
a drain pad of the second peak transistor is provided adjacent to the second peak transistor in a direction perpendicular to the signal propagation direction.

11. The Doherty amplifier according to claim 10, wherein a bonding wire connected to the drain pad of the second peak transistor is inclined by 90 degrees or more relative to a bonding wire connected to a drain pad of the second main transistor.

12. A Doherty amplifier, comprising:
an input terminal;
an output terminal;
a first main transistor provided in a first signal path connecting the input terminal and the output terminal;
a first peak transistor provided in a second signal path connecting the input terminal and the output terminal;
a first matching circuit provided in the first signal path; and
a second matching circuit provided in the second signal path, wherein
the first main transistor and the first peak transistor are provided on a first semiconductor chip, and
the first matching circuit and the second matching circuit are provided on a second semiconductor chip.

13. The Doherty amplifier according to claim 12, further comprising:
a second main transistor provided on the output terminal side of the first main transistor in the first signal path; and
a second peak transistor provided on the output terminal side of the first peak transistor in the second signal path, wherein
the second main transistor and the second peak transistor are provided on the first semiconductor chip.

14. The Doherty amplifier according to claim 13, wherein the first main transistor and the first peak transistor are provided inside the second main transistor and the second peak transistor.

15. The Doherty amplifier according to claim 13, wherein
the first matching circuit is provided between the first main transistor and the second main transistor, in the first signal path, and
the second matching circuit is provided between the first peak transistor and the second peak transistor, in the second signal path.

16. The Doherty amplifier according to claim 12, wherein a first bonding wire connecting semiconductor chips in the first signal path and a second bonding wire connecting semiconductor chips in the second signal path are not parallel to each other.
